(19) United States
(12) Patent Application Publication
(10) Pub. No.: US 2019/0148487 A1
(43) Pub. Date: May 16, 2019

(54) SEMICONDUCTOR DEVICE INCLUDING PARTITIONING LAYER EXTENDING BETWEEN GATE ELECTRODE AND SOURCE ELECTRODE

(71) Applicant: Sanken Electric Co., Ltd., Niiza-shi (JP)

(72) Inventors: Shunsuke FUKUNAGA, Saitama-shi (JP); Taro KONDO, Niiza-shi (JP); Shinji KUDO, Yoshimi-machi (JP)

(73) Assignee: Sanken Electric Co., Ltd., Niiza-shi (JP)

(21) Appl. No.: 15/814,070

(22) Filed: Nov. 15, 2017

(51) Int. Cl. H01L 29/06; H01L 29/16; H01L 29/20

(52) U.S. Cl. CPC H01L 29/0649; H01L 29/2003; H01L 29/1608

(57) ABSTRACT

A semiconductor device that includes a semiconductor substrate; a trench in the semiconductor substrate; a gate electrode in the trench; a source electrode in the trench, the source electrode being disposed between the gate electrode and a bottom wall of the trench; a partitioning layer in the trench, the partitioning layer extending between the gate electrode and the source electrode; and an insulating film in the trench.

### FIELD

The present disclosure generally relates to semiconductor device(s) and more particularly to fabrication of the semiconductor device(s) with partitioning layer extending between gate electrode and source electrode.

### BACKGROUND

Semiconductor switching devices are used for switching or controlling power in electrical circuits. The semiconductor switching devices may be switched at high speed and have high maximum blocking voltage capability. In an example, the semiconductor switching devices may include power semiconductor devices. It is desirable to have high switching speed for the power semiconductor devices that are used for switching. The power semiconductor devices are widely used in power supply devices, motor drive circuits, integrated Circuit (IC) devices, etc. for switching. An example of a power semiconductor device includes a power Metal Oxide Semiconductor Field Effect Transistor (MOSFET). However, the high switching speed of the power semiconductor devices may lead to switching noise in the power semiconductor devices due to parasitic capacitance. Further, the switching noise may cause malfunction of the power semiconductor devices.

U.S. Pat. No. 5,998,833, hereinafter referred to as '833 patent, describes integrated power semiconductor devices. The integrated power semiconductor devices include Graded-doped (GD)-UMOSFET unit cells with upper trench-based gate electrodes and lower trench-based source electrodes. The '833 patent describes a semiconductor device having an insulating layer with low relative permittivity. The low relative permittivity reduces switching capacitance of the insulating film, which may further lead to noise in the semiconductor device.

### SUMMARY

In one aspect of the present disclosure, there is provided a semiconductor device, comprising: a semiconductor substrate; a trench in the semiconductor substrate; a gate electrode in the trench; a source electrode in the trench, the source electrode being disposed between the gate electrode and a bottom wall of the trench; a partitioning layer in the trench, the partitioning layer extending between the gate electrode and the source electrode; and an insulating film in the trench.

### BRIEF DESCRIPTION OF THE DRAWINGS

The accompanying drawings, which are incorporated in and constitute a part of the specification, are illustrative of one or more embodiments and, together with the description, explain the embodiments. The accompanying drawings have not necessarily been drawn to scale. Further, any values or dimensions in the accompanying drawings are for illustration purposes only and may or may not represent actual or preferred values or dimensions. Where applicable, some or all select features may not be illustrated to assist in the description and understanding of underlying features.

FIG. 1(A) illustrates a schematic cross-sectional view of a semiconductor device, according to an embodiment of the present disclosure;

FIG. 1(B) illustrates the schematic cross-sectional view of the semiconductor device, according to another embodiment of the present disclosure;

FIG. 2(A) illustrates a schematic cross-sectional view of the semiconductor device, according to another embodiment of the present disclosure;

FIG. 2(B) illustrates a schematic cross-sectional view of the semiconductor device, according to another embodiment of the present disclosure;

FIG. 2(C) illustrates a schematic cross-sectional view of the semiconductor device, according to another embodiment of the present disclosure;

FIG. 3 illustrates a schematic exploded representation of a partitioning layer of the semiconductor device, according to one embodiment of the present disclosure;

FIG. 4 illustrates a schematic exploded representation of the partitioning layer having multiple layers in the semiconductor device, according to one embodiment of the present disclosure;

FIG. 5 illustrates an exemplary graph of switching noise versus ratio of thickness of the partitioning layer of the semiconductor device in a central area and the thickness of the partitioning layer in a peripheral area, according to one embodiment of the present disclosure;

FIG. 6 illustrates an exemplary graph of electrical stability versus ratio of width of the partitioning layer of the semiconductor device and width of a gate electrode or width of a source electrode of the semiconductor device, according to one embodiment of the present disclosure;

FIG. 7(A) illustrates a schematic cross-sectional view of an intermediate structure during fabrication of the semiconductor device, according to one embodiment of the present disclosure;

FIG. 7(B) further illustrates the schematic cross-sectional view of the intermediate structure during fabrication of the semiconductor device, according to one embodiment of the present disclosure;

FIG. 7(C) further illustrates the schematic cross-sectional view of the intermediate structure during fabrication of the semiconductor device, according to one embodiment of the present disclosure;

FIG. 7(D) further illustrates the schematic cross-sectional view of the intermediate structure during fabrication of the semiconductor device, according to one embodiment of the present disclosure;

FIG. 7(E) further illustrates the schematic cross-sectional view of the intermediate structure during fabrication of the semiconductor device, according to one embodiment of the present disclosure;

FIG. 7(F) further illustrates the schematic cross-sectional view of the intermediate structure during fabrication of the semiconductor device, according to one embodiment of the present disclosure;

FIG. 7(G) further illustrates the schematic cross-sectional view of the intermediate structure during fabrication of the semiconductor device, according to one embodiment of the present disclosure;

FIG. 7(H) further illustrates the schematic cross-sectional view of the intermediate structure during fabrication of the semiconductor device, according to one embodiment of the present disclosure;

FIG. 7(I) further illustrates the schematic cross-sectional view of the intermediate structure during fabrication of the semiconductor device, according to one embodiment of the present disclosure;

FIG. 7(J) further illustrates the schematic cross-sectional view of the intermediate structure during fabrication of the semiconductor device, according to one embodiment of the present disclosure;

FIG. 7(K) further illustrates the schematic cross-sectional view of the intermediate structure during fabrication of the semiconductor device, according to one embodiment of the present disclosure;

FIG. 8 illustrates a process of formation of the partitioning layer, according to one embodiment of the present disclosure; and

FIG. 9 illustrates a flowchart of a method of fabricating a semiconductor device, according to one embodiment of the present disclosure.

### DETAILED DESCRIPTION

The description set forth below in connection with the appended drawings is intended as a description of various embodiments of the described subject matter and is not necessarily intended to represent the only embodiment(s). In certain instances, the description includes specific details for the purpose of providing an understanding of the described subject matter. However, it will be apparent to those skilled in the art that embodiments may be practiced without these specific details. In some instances, well-known structures and components may be shown in block diagram form in order to avoid obscuring the concepts of the described subject matter. Wherever possible, corresponding or similar reference numbers will be used throughout the drawings to refer to the same or corresponding parts.

Any reference in the specification to “one embodiment” or “an embodiment” means that a particular feature, structure, characteristic, operation, or function described in connection with an embodiment is included in at least one embodiment. Thus, any appearance of the phrases “in one embodiment” or “in an embodiment” in the specification is not necessarily referring to the same embodiment. Further, the particular features, structures, characteristics, operations, or functions may be combined in any suitable manner in one or more embodiments, and it is intended that embodiments of the described subject matter can and do cover modifications and variations of the described embodiments.

It must also be noted that, as used in the specification, appended claims and abstract, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the described subject matter to any particular orientation or configuration. Furthermore, terms such as “first,” “second,” “third,” etc. merely identify one of a number of portions, components, points of reference, operations or functions as described herein, and likewise do not necessarily limit embodiments of the described subject matter to any particular configuration, orientation, or sequence of functions or operations.

Generally speaking, embodiments of the present disclosure provide a semiconductor device and a method of fabricating the semiconductor device. More specifically, embodiments of the present disclosure provide a semiconductor device and a method of fabricating the semiconductor device, such that switching noise associated with the semiconductor device can be controlled or reduced. The semiconductor device of the present disclosure includes a partitioning layer along with an insulating film. Relative permittivity of the partitioning layer is higher than relative permittivity of the insulating film. As a result, capacitance of the partitioning layer becomes higher than capacitance of the insulating film. Consequently, the switching noise in the semiconductor device that occurs due to the insulating film having lower relative permittivity may be reduced or controlled.

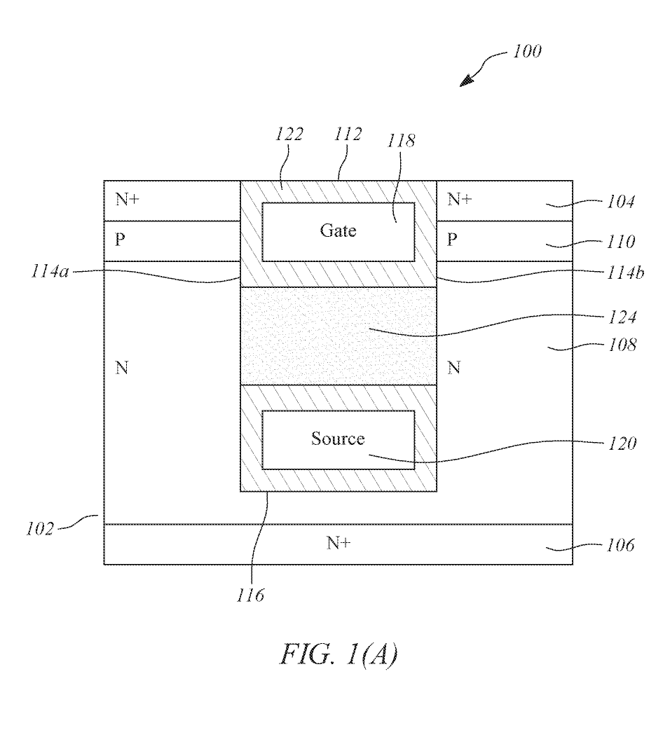

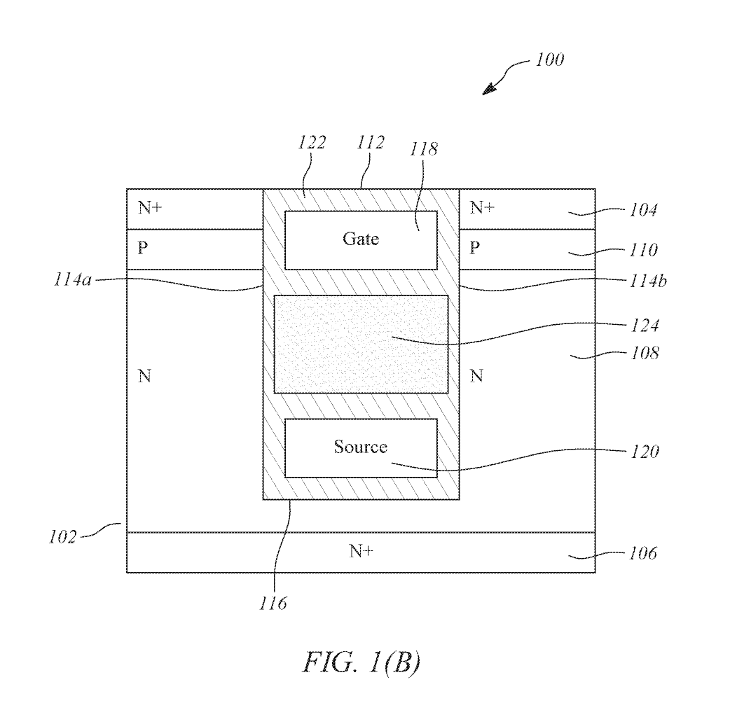

Referring to FIG. 1(A), a schematic cross-sectional view of a semiconductor device 100, according to an embodiment of the present disclosure is illustrated. In an example, the semiconductor device 100 may be a U-Shape Metal Oxide Semiconductor Field Effect Transistor (UMOSFET). The semiconductor device 100 includes a semiconductor substrate 102. The semiconductor device 100 further includes a source layer 104 and a drain layer 106. The source layer 104 and the drain layer 106 are highly doped layers of a first conductivity type, for example, of “N+” conductivity type. The semiconductor device 100 further includes a drift layer 108 of the first conductivity type, for example, of “N” conductivity type. The drift layer 108 may have a linearly graded doping concentration therein. In an example, the semiconductor substrate 102 is formed by depositing the drift layer 108 on the drain layer 106. The semiconductor device 100 also includes a base layer 110 of a second conductivity type different from the first conductivity type, for example, of “P” conductivity type.

The semiconductor device 100 further includes a trench 112 having a pair of opposing side walls, such as a first sidewall 114a and a second sidewall 114b. The trench 112 also includes a bottom wall 116. The trench 112 is formed in the semiconductor substrate 102. The semiconductor device 100 also includes a gate electrode 118 and a source electrode 120. The gate electrode 118 and the source electrode 120 are provided in the trench 112, such that the source electrode 120 is disposed between the gate electrode 118 and the bottom wall 116 of the trench 112. In an example, the gate electrode 118 and the source electrode 120 may comprise polysilicon. Further, the gate electrode 118 and the source electrode 120 may have equal width.

The semiconductor device 100 also includes an insulating film 122. The insulating films 122 extends along the first sidewall 114a and the second sidewall 114b of the trench 112. between the gate electrode 118 and the source electrode 120, and further between the source electrode 120 and the bottom wall 116 of the trench 112. In an example, the insulating film 122 comprises Silicon Dioxide (SiO₂). Relative permittivity of SiO₂ is 3.9.

The semiconductor device 100 further includes a partitioning layer 124 in the trench 112. The partitioning layer 124 extends between the gate electrode 118 and the source electrode 120. Further, a width of the partitioning layer 124 in a width direction is larger than a width of each of the gate electrode 118 and the source electrode 120 in the width direction. The width direction is perpendicular to a depth direction of the trench 112. In an example, the width of the partitioning layer 124 is about 1.2 times to about 2.5 times larger than the width of each of the gate electrode 118 and the source electrode 120, and preferably about 1.5 times to about 2.1 times larger.

Referring to FIG. 1(B), the insulating film 122 may further extend between the partitioning layer 124, the first sidewall 114a and the second sidewall 114b of the trench 112 in another embodiment of the disclosure.

Further, the partitioning layer 124 may have a pre-defined thickness profile. Thickness of the partitioning layer 124 in a central area of the partitioning layer 124 in a width direction is more than the thickness of the partitioning layer in a peripheral area of the partitioning layer in the width direction. In an example, the reduction in the switching noise of the semiconductor device 100 may depend on the pre-defined thickness profile of the partitioning layer 124. Examples of the pre-defined thickness profile of the partitioning layer 124 may include, but are not limited to, a planar profile, a spherical profile, a triangular profile, and a trapezoidal profile.

According to an embodiment, relative permittivity of the partitioning layer 124 is higher than the relative permittivity of the insulating film 122. The partitioning layer 124 comprises at least one of Silicon nitride (Si₃N₄), Aluminum Oxide (Al₂O₃), Silicon (Si), Silicon carbide (SiC), and Gallium nitride (GaN). The relative permittivity of Si₃N₄ is 7.5, the relative permittivity of Al₂O₃ is 8, the relative permittivity of Si is 11.2, the relative permittivity of SiC is 9.7, and the relative permittivity of GaN is 9.

According to an embodiment, the partitioning layer 124 includes a single layer. According to another embodiment, the partitioning layer 124 may include a plurality of layers. In one example, each layer includes a different material, also referred to as partitioning material. In another example, two or more layers may include the same partitioning material. Further, the partitioning materials are deposited in multiple layers in order of relative permittivity of the partitioning materials, such that relative permittivity of the layers disposed near the source electrode 120 is higher than the relative permittivity of the layers disposed near the gate electrode 118. In an example, the partitioning layer 124 may include two layers, namely a first layer and a second layer. The first layer is disposed near the gate electrode 118 and the second layer is disposed near the source electrode 120. According to said example, the first layer may comprise Si₃N₄ (relative permittivity ε=7.5) and the second layer may comprise Si (Relative permittivity ε=11.2). Additionally, the relative permittivity of each layer is higher than the relative permittivity of the insulating film 122. By gradually changing the relative permittivity of each layer, the switching noise of the semiconductor device 100 may be significantly reduced.

The capacitance of the semiconductor device 100 may be controlled by using different partitioning materials. For instance, since the relative permittivity of each layer is higher than the relative permittivity of the insulating layer 122, capacitance of the each layer also becomes higher than capacitance of the insulating layer 122. Consequently, a relationship between the switching speed and the switching noise in the semiconductor device 100 may be controlled. For instance, by changing the relative permittivity, various capacitances occur between the gate electrode 118 and the source electrode 120 which control switching time of the semiconductor device 100. As a result, the switching time increases and leads to a reduction in the switching noise of the semiconductor device 100.

According to an embodiment, if a partitioning material having a thermal expansion coefficient closer to a thermal expansion coefficient of the insulating film 122 is used in the partitioning layer 124, total stress of deposited materials filling the trench 112 may he reduced. In an example, the thermal expansion coefficient of the insulating film 122 comprising SiO₂ is 0.5×10⁻⁶/K and the thermal expansion coefficient of Si₃N₄ is 3.5×10⁻⁶/K. Accordingly, if the partitioning layer 124 comprises Si₃N₄, then the total stress of the deposited material filling the trench 112 is reduced to a significant level.

Further, an edge of each of the plurality of layers of the partitioning layer 124 is on a same plane. If a single material contacts the side wall of the trench 112, a depletion layer extends. This increases a break down voltage. Consequently, a capacity to withstand voltage is improved. The capacity to withstand the voltage (also referred as break down voltage) may be improved if the depletion layer extends. If the depletion layer does not extend, then electric field that is formed by the depletion layer, is partially concentrated and the capacity to withstand the voltage may be decreased. On the contrary, the break down voltage increases if one material is contacting the side wall of the trench 112 because if one material is contacting the side wall of the trench 112, then the depletion layer extends, which results in the improvement of capacity.

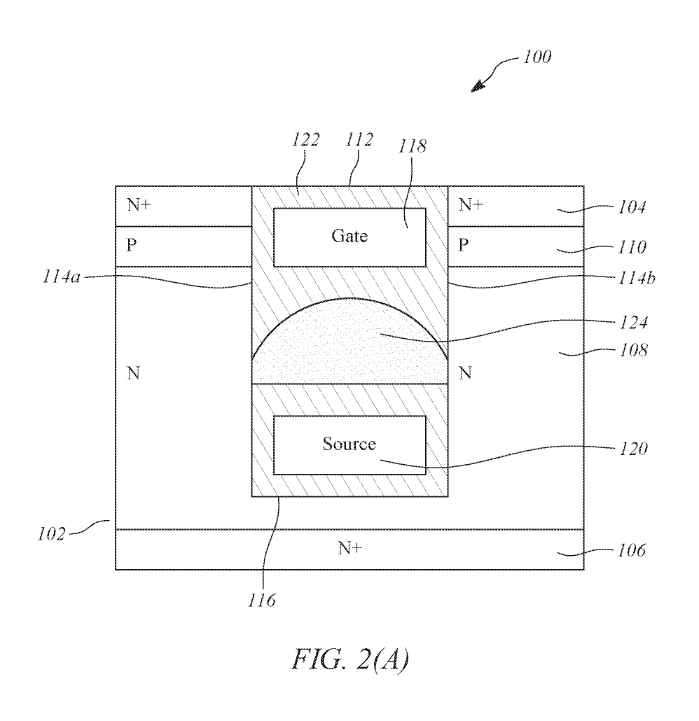

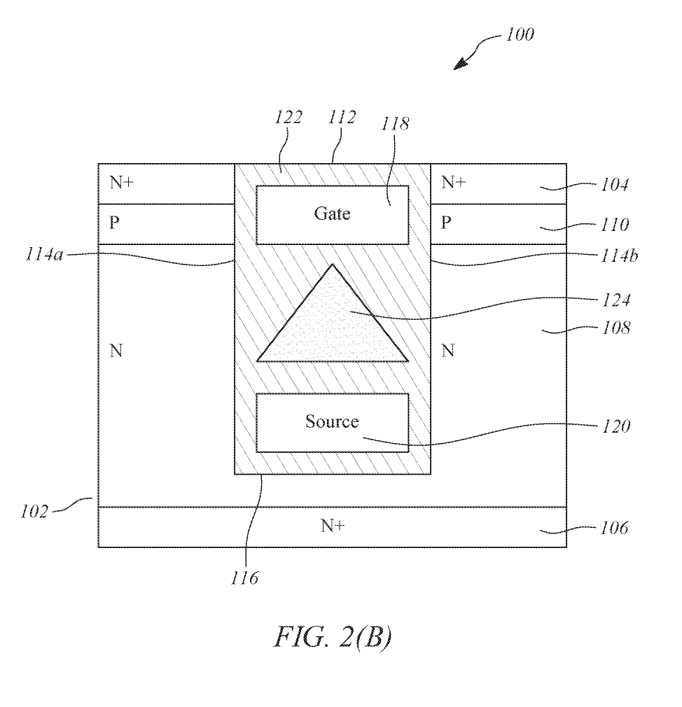

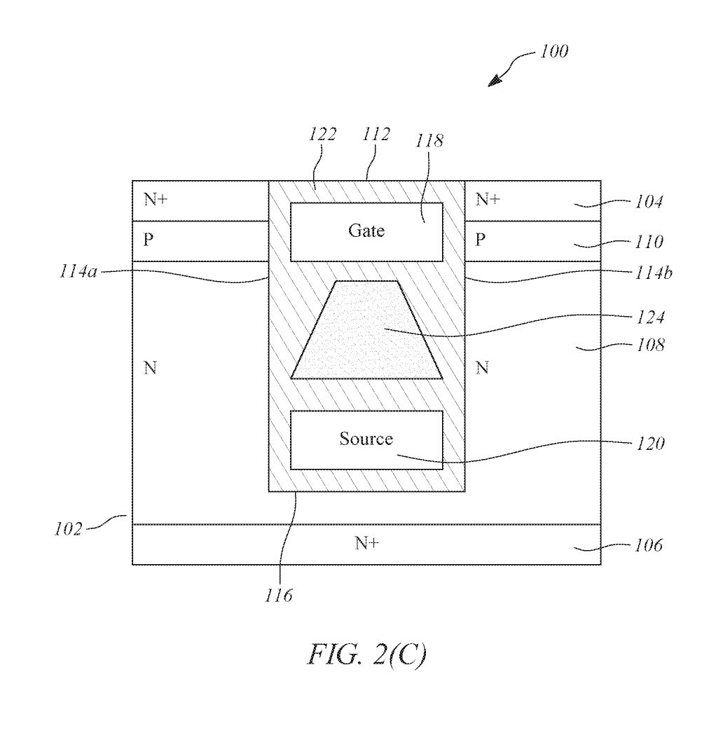

FIG. 2(A) illustrates a schematic cross-sectional view of the semiconductor device 100, according to another embodiment of the present disclosure.

As described above, the reduction in the switching noise of the semiconductor device 100 may depend on the pre-defined thickness profile of the partitioning layer 124. The FIG. 2(A) illustrates the spherical profile of the partitioning layer 124 according to one embodiment, Further, FIG. 2(B) illustrates the triangular profile of the partitioning layer 124 according to an embodiment. Furthermore, FIG. 2(C) illustrates the trapezoidal profile of the partitioning layer 124 according to an embodiment.

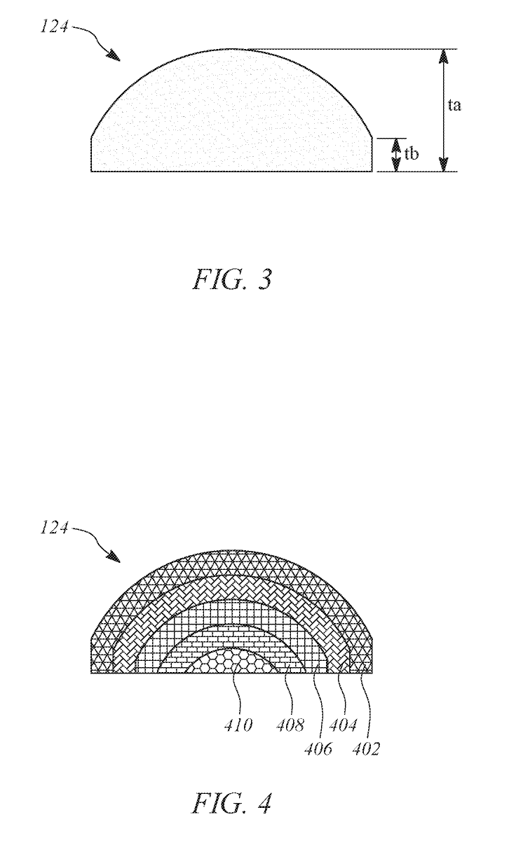

The manner in which the spherical profile of the partitioning layer 124 helps in reducing the switching noise is further described in detail in conjunction with FIG. 3, FIG. 4, and FIG. 5.

FIG. 3 illustrates a schematic exploded representation of the partitioning layer 124 of the semiconductor device 100, according to one embodiment of the present disclosure.

As shown in FIG. 3, the partitioning layer 12.4 is of a spherical profile. A bottom surface of the partitioning layer 124 closer to the source electrode than the gate electrode in the depth direction is flat and upper surface of the partitioning layer 124 closer to the gate electrode than the source electrode in the depth direction is convex. If the partitioning layer 124 is flat, then dielectric constant between the gate electrode 118 and the source electrode 120 is constant along the length of the gate electrode 118 and the source electrode 120. On the other hand, when the partitioning layer 124 has the spherical shape, the dielectric constant between the gate electrode 118 and the source electrode 120 varies along the length of the gate electrode 118 and the source electrode 120. This decreases switching speed between the gate electrode 118 and the source electrode 120 and switching waveform rises slowly. As a result, the switching noise reduces. As may be seen in FIG. 3, the thickness of the partitioning layer 124 in a central area (denoted by ta) is more than the thickness of the partitioning layer 124 in a peripheral area (denoted by tb). In an example, a ratio of the thickness of the partitioning layer 124 in the central area and the thickness of the partitioning layer 124 in the peripheral area (ta/tb) is greater than about 1.2. For instance, the ratio of ta/tb may be in between 1.2 and 2.4, preferably between 1.3 and 1.8. Since the thickness of the partitioning layer 124 in the peripheral area is less than the thickness of the partitioning layer 124 in the central area, the capacitance of the peripheral area increases. As a consequence, the switching noise of the semiconductor device 100 decreases.

FIG. 4 illustrates a schematic exploded representation of the partitioning layer 124 having multiple layers in the semiconductor device 100, according to one embodiment of the present disclosure.

The FIG. 4 depicts five layers of the partitioning layer 124 i.e. a first layer 402, a. second layer 404, a third layer 406, a fourth layer 408, and a fifth layer 410. The first layer 402 is a top-most layer and is disposed near the gate electrode 118 of the semiconductor device 100 and the fifth layer 410 is a bottom-most layer and is disposed near the source electrode 120 of the semiconductor device 100. According to an example, the first layer 402 may comprise Si₃N₄ (relative permittivity ε=7.5), the second layer 404 comprises Al₂O₃ (relative permittivity ε=8), the third layer 406 comprises GaN (relative permittivity ε=9), the fourth layer 408 comprises SiC (relative permittivity ε=9.7), and the fifth layer 410 may comprise Si (relative permittivity ε=11.2). Thus, the relative permittivity of the partitioning layer 124 becomes lower (i.e.=7.5) as the partitioning layer 124 approaches the gate electrode 118, while the relative permittivity of the partitioning layer 124 becomes higher (i.e.=11.2) as the partitioning layer 124 approaches the source electrode 120.

Since, the relative permittivity of the first layer 402, the second layer 404, the third layer 406, the fourth layer 408, and the fifth layer 410 gradually changes, and the relative permittivity of the fifth layer 410 is highest in comparison to other layers, the switching noise of the semiconductor device 100 is significantly reduced. Further, since the first layer 402, the second layer 404, the third layer 406, the fourth layer 408, and the fifth layer 410 comprise different partitioning materials with different relative permittivity, i.e., Si₃N₄ (relative permittivity ε=7.5), Al₂O₃ (relative permittivity ε=8), GaN (relative permittivity ε=9), SiC (relative permittivity ε=9.7), and Si (relative permittivity ε=11.2), various capacitances occur between the gate electrode 118 and the source electrode 120, controlling the switching noise of the semiconductor device 100.

FIG. 5 illustrates an exemplary graph 500 of switching noise versus ratio of the thickness of the partitioning layer 124 of the semiconductor device 100 in the central area and the thickness of the partitioning layer 124 in the peripheral area (ta/tb), according to one embodiment of the present disclosure.

As shown in FIG. 5, X-axis of the graph 500 represents the ratio of ta and tb, (ta/tb). Further Y-axis of the graph 500 represents switching noise of the semiconductor device 100 in percentage. It should be understood that the switching noise at various ratios of ta and tb is shown as a percentage of the switching noise when ta and tb are the same the ratio of ta and tb is equal to 1). Thus, the switching noise at ta/tb=1 is shown to be 100 percent. As can be seen in the graph 500, when the ratio of ta and tb (ta/tb) is between 1 and 1.1, the switching noise of the semiconductor device 100 is approximately 100 percent. Further, when the ratio of ta and tb (ta/tb) is 1.2, the switching noise of the semiconductor device 100 is reduced to 99 percent. Furthermore, when the ratio of ta and tb (ta/tb) is 1.3, the switching noise of the semiconductor device 100 is further reduced to 95 percent. When the ratio of ta and tb (ta/tb) is 1.4, the switching noise of the semiconductor device 100 is reduced to 93 percent and when the ratio of ta and tb (ta/tb) is 1.5, the switching noise of the semiconductor device 100 is further reduced to 92 percent. Further, when the ratio of ta and tb (ta/tb) is 1.6, the switching noise of the semiconductor device 100 is further reduced to 91 percent. Thus, as the ratio of ta and tb (ta/tb) increases, the switching noise reduces. For instance, when the ratio of ta and tb (ta/tb) is 1.6, the switching noise of the semiconductor device 100 is reduced to 91 percent. Accordingly, when the ratio of ta and tb (ta/tb) is 1.2 and above, the change of dielectric constant between source electrode and gate electrode gradually reduces the switching noise.

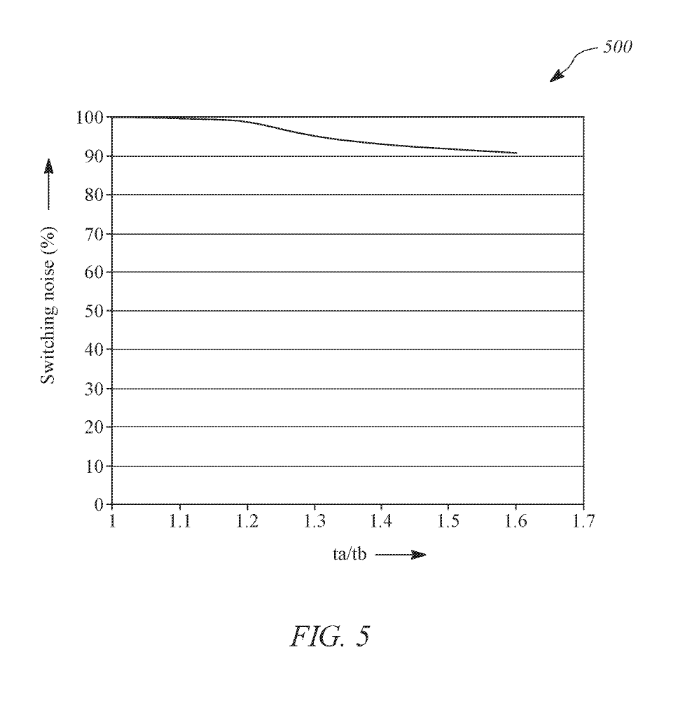

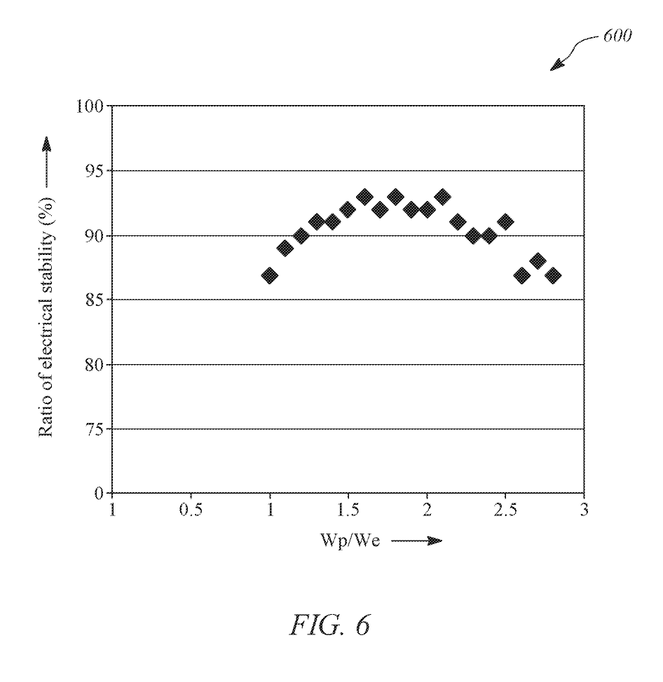

FIG. 6 illustrates an exemplary graph 600 of electrical stability versus ratio of width of the partitioning layer 124 of the semiconductor device 100 and a width of the gate electrode 118 or a width of the source electrode 120 of the semiconductor device 100, according to one embodiment of the present disclosure.

As shown in FIG. 6, X-axis of the graph 600 represents the ratio of width of the partitioning layer 124 and width of the gate electrode 118 or the source electrode 120. The width of the partitioning layer 124 is denoted by Wp and the width of the gate electrode 118 or the width of the source electrode 120 is denoted by We. Further, Y-axis of the graph 600 represents electrical stability of the semiconductor device 100 in percentage, As can be seen in the graph 600, when the ratio of Wp and We (Wp/We) is 1, the electrical stability of the semiconductor device 100 is 87 percent. Further, when the ratio of Wp and We (Wp/We) is 1.1, the electrical stability of the semiconductor device 100 increases to 89 percent. As shown in the graph 600, the electrical stability of the semiconductor device 100 is maximum (93 percent) when the ratios of Wp and We (Wp/We) are 1.6, 1.8, and 2.1. Further, the electrical stability of the semiconductor device 100 is minimum (87 percent) when the ratios of Wp and We (Wp/We) are 1 and 2.6.

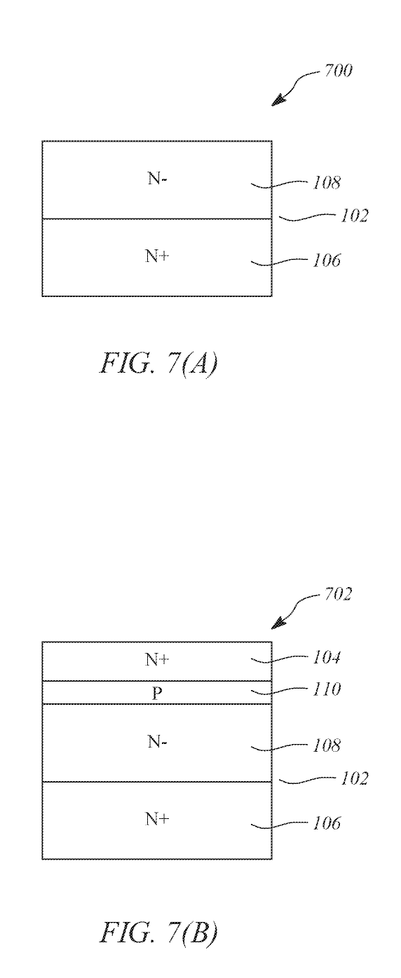

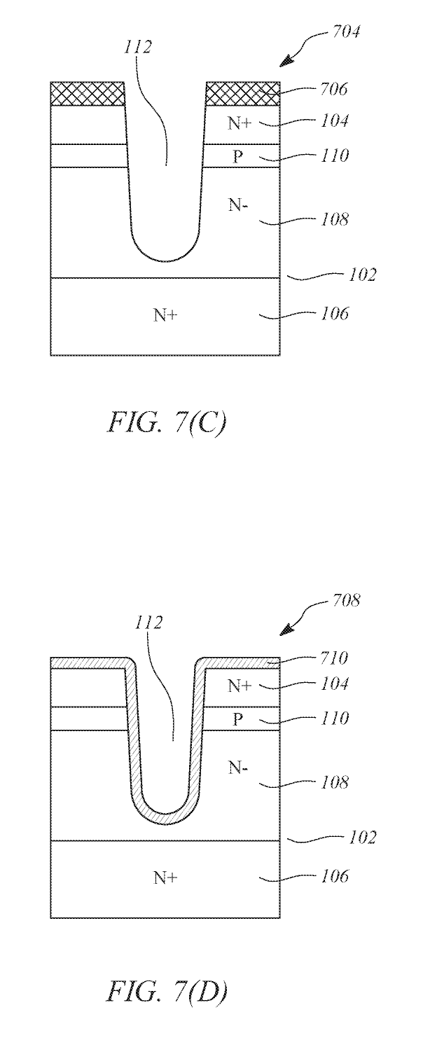

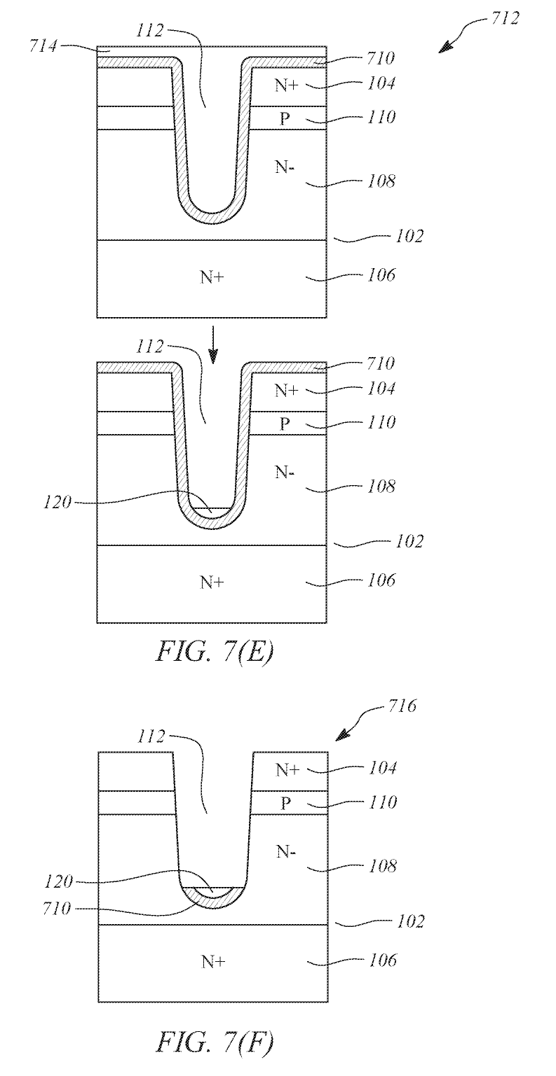

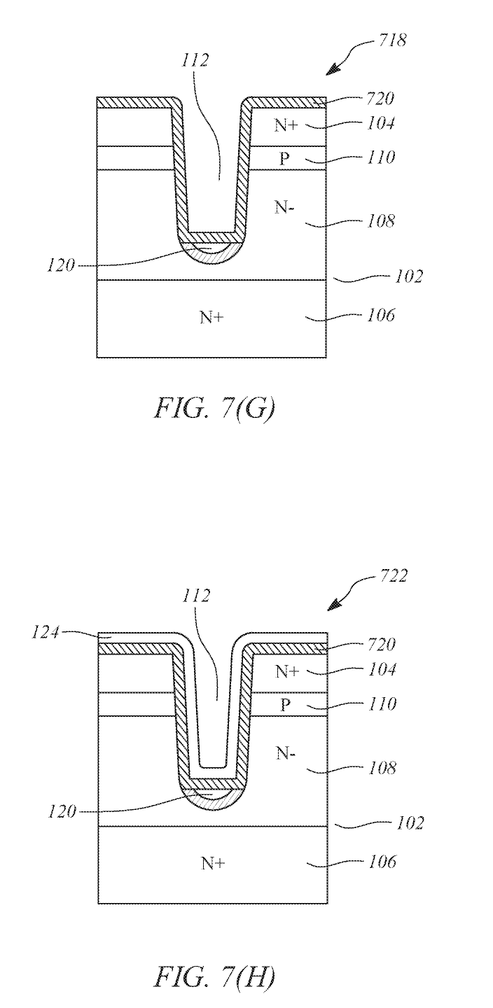

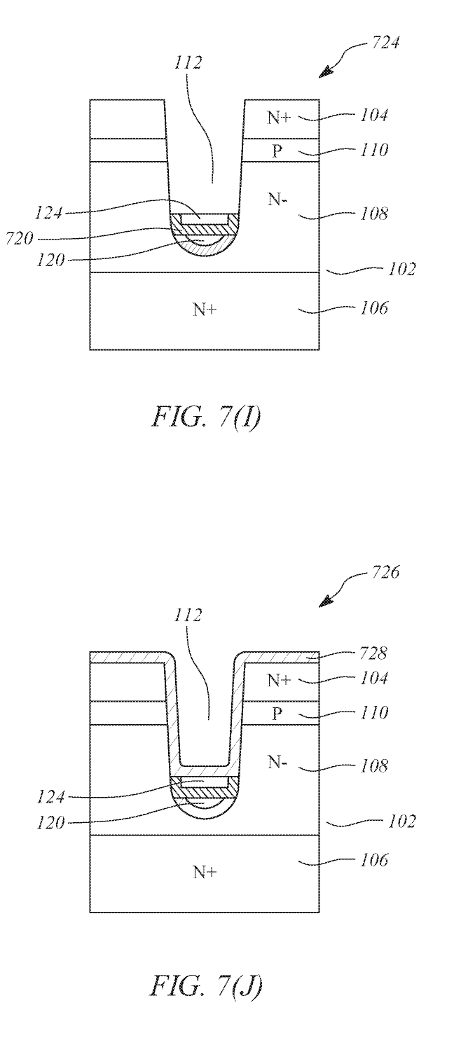

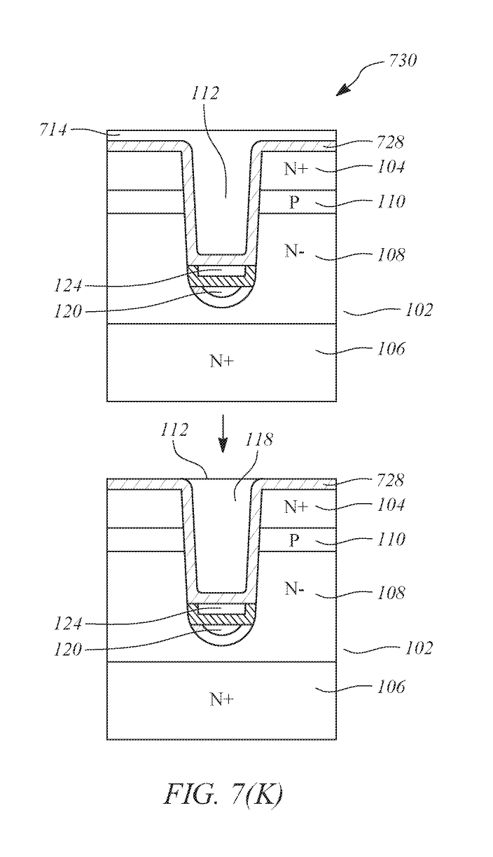

FIG. 7(A) illustrates a schematic cross-sectional view of an intermediate structure 700 during fabrication of the semiconductor device 100, according to one embodiment of the present disclosure. In an example, the semiconductor device 100 is fabricated using the process illustrated below.

As can be seen in the FIG. 7(A), the semiconductor substrate 102 is formed by depositing the drift layer 108 on the drain layer 106. In an example, the drain layer 106 is an N+ silicon substrate and the drift layer 108 is an N− semiconductor layer. According to an example, the semiconductor substrate 102 may be formed by an epitaxial growth technique.

FIG. 7(B) further illustrates the schematic cross-sectional view of the intermediate structure 702 during fabrication of the semiconductor device 100, according to one embodiment of the present disclosure.

As can be seen in the FIG. 7(B), the base layer 110 of a second conductivity type different from the first conductivity type, for example, of “P” conductivity type is formed on the surface of the drift layer 108. In an example, P type impurities, such as Boron ions are implanted on the entire surface of the semiconductor substrate 102. Once the P type impurities are implanted on the semiconductor substrate 102, the structure 702 is subjected to heat treatment as around 1000° C. to around 1200° C., Consequently, the P type impurities are diffused and the base layer 110 is formed. Once the base layer 110 is formed, the source layer 104 is formed on the surface of the base layer 110. The source layer 104 is a highly doped layer of a first conductivity type, for example, of “N+” conductivity type. In an example, N type impurities, such as phosphorous ions are implanted on the entire surface of the semiconductor substrate 102. Thereafter, the structure 702 is subjected to heat treatment at around 1000° C. to around 1200° C. As a result, N type impurities are diffused and the source layer 104 is formed.

FIG. 7(C) furthermore illustrates the schematic cross-sectional view of the intermediate structure 704 during fabrication of the semiconductor device 100, according to one embodiment of the present disclosure.

As can be seen in the FIG. 7(C), a mask 706 is formed and the trench 112 is formed in the semiconductor substrate 102. In an example, the trench 112 is formed in a way that it penetrates through the source layer 104 and the base layer 110, and reaches the drift layer 108. According to an example, the trench etching is performed using a dry etching process. Further, the mask 706 is removed after the trench etching process.

FIG. 7(D) furthermore illustrates the schematic cross-sectional view of the intermediate structure 708 during fabrication of the semiconductor device 100, according to one embodiment of the present disclosure.

As can be seen in the FIG. 7(D), a first insulating film 710 is formed on an inner wall of the trench 112 and on the entire surface of the semiconductor substrate 102. The first insulating film 710 is formed by an oxidation process. In an example, the first insulating film 710 comprises SiO₂.

FIG. 7(E) furthermore illustrates the schematic cross-sectional view of the intermediate structure 712 during fabrication of the semiconductor device 100, according to one embodiment of the present disclosure.

As can be seen in the FIG. 7(E), polysilicon material 714 is deposited on the entire surface of the semiconductor substrate 102, thereby filling the trench 112. Once the polysilicon material 714 is deposited on the surface of the semiconductor substrate 102, the polysilicon material 714 deposited surface is etched back. As the result, a source electrode 120, also referred to as field plate is formed at the bottom of the trench 112.

FIG. 7(F) furthermore illustrates the schematic cross-sectional view of the intermediate structure 716 during fabrication of the semiconductor device 100, according to one embodiment of the present disclosure.

As can be seen in the FIG. 7(F), the first insulating film 710 formed on the inner wall of the trench 112 and the surface of the semiconductor substrate 102 is removed. The portion of the first insulating film 710 is removed from above the source electrode 120. In an example, the first insulating film 710 may removed by an etching process.

FIG. 7(G) furthermore illustrates the schematic cross-sectional view of the intermediate structure 718 during fabrication of the semiconductor device 100, according to one embodiment of the present disclosure.

As can be seen in the FIG. 7(G), the entire surface of the semiconductor substrate 102 is thermally oxidized once again, to fort a second insulating film 720 on the inner wall of the trench 112 and the surface of the semiconductor substrate 102. In an example, the second insulating film 720 comprises SiO₂.

FIG. 7(H) furthermore illustrates the schematic cross-sectional view of the intermediate structure 722 during fabrication of the semiconductor device 100, according to one embodiment of the present disclosure.

As can be seen in the FIG. 7(H), a partitioning layer 124 is deposited on the entire surface of the semiconductor substrate 102, thereby filling the trench 112. In an example, thickness of the partitioning layer 124 in the depth direction is in a range of about 50 Å to about 1000 Å. The partitioning layer 124 is deposited using at least one of a sputtering technique, a Chemical Vapor Deposition (CVD) technique, and an epitaxial growth technique.

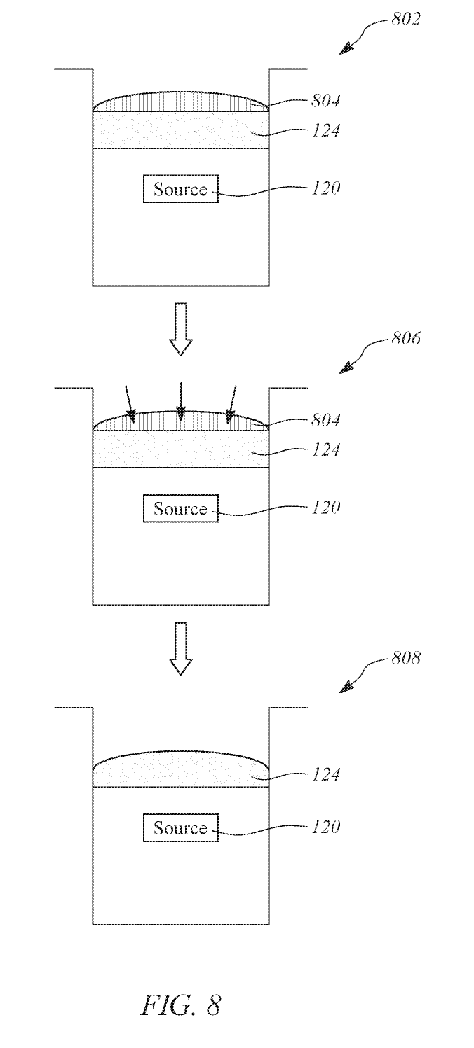

Once the partitioning layer 124 is deposited, the entire surface of the semiconductor substrate 102 is etched back using dry etching. As a result, the partitioning layer 124 is formed in the trench 112. In an example, the surface of the semiconductor substrate 102 is etched using at least one of Fluoroform (CHF₃), Sulfur Hexafluoride (SF₆), Nitrogen trifluoride (NF₃), Hydrogen bromide (HBr), and Argon (Ar) gas. By repeating steps depicted in FIG. 7(H) and FIG. 7(I), the partitioning layer 124 including a plurality of partitioning layers is formed. An exemplary process for forming the partitioning layer 124 with a desired thickness profile is further explained in conjunction with FIG. 8.

FIG. 7(I) furthermore illustrates the schematic cross-sectional view of the intermediate structure 724 during fabrication of the semiconductor device 100, according to one embodiment of the present disclosure.

As can be seen in the FIG. 7(I), a portion of the second insulating film 720 is removed from the surface of the semiconductor substrate 10. In an example, the second insulating film 720 is removed using the etching process.

FIG. 7(J) furthermore illustrates the schematic cross-sectional view of the intermediate structure 726 during fabrication of the semiconductor device 100, according to one embodiment of the present disclosure.

As can be seen in the FIG. 7(J), the entire surface of the semiconductor substrate 102 is thermally oxidized again to form a third insulating film 728 on the inner wall of the trench 112 and the surface of the semiconductor substrate 102.

FIG. 7(K) furthermore illustrates the schematic cross-sectional view of the intermediate structure 730 during fabrication of the semiconductor device 100, according to one embodiment of the present disclosure.

As can be seen in the FIG. 7(K), the polysilicon material 714 is deposited on the entire surface of the semiconductor substrate 102, thereby filling the trench 112. Once the polysilicon material 714 is deposited on the surface of the semiconductor substrate 102, the surface is etched back. As a result, a gate electrode 118 is formed in trench 112.

FIG. 8 illustrates a process of formation of the partitioning layer 124 having the spherical profile, according to one embodiment of the present disclosure.

As shown in FIG. 8, at step 802, a photo mask 804 is formed on the surface of the partitioning layer 124. The photo mask has a spherical profile. In an example, the photo mask 804 is a positive type photo resist.

Further, at step 806, the entire surface of the photo mask 804 is subjected to dry etching. In an example, Krypton Fluoride (KrF) excimer laser or Argon fluoride (ArF) excimer laser is used as a light source for dry etching.

At step 808, the partitioning layer 124 having the spherical profile is formed as a result of dry etching process. In a similar manner, the partitioning layer 124 having other thickness profiles such as triangular profile or trapezoidal profile, may be formed.

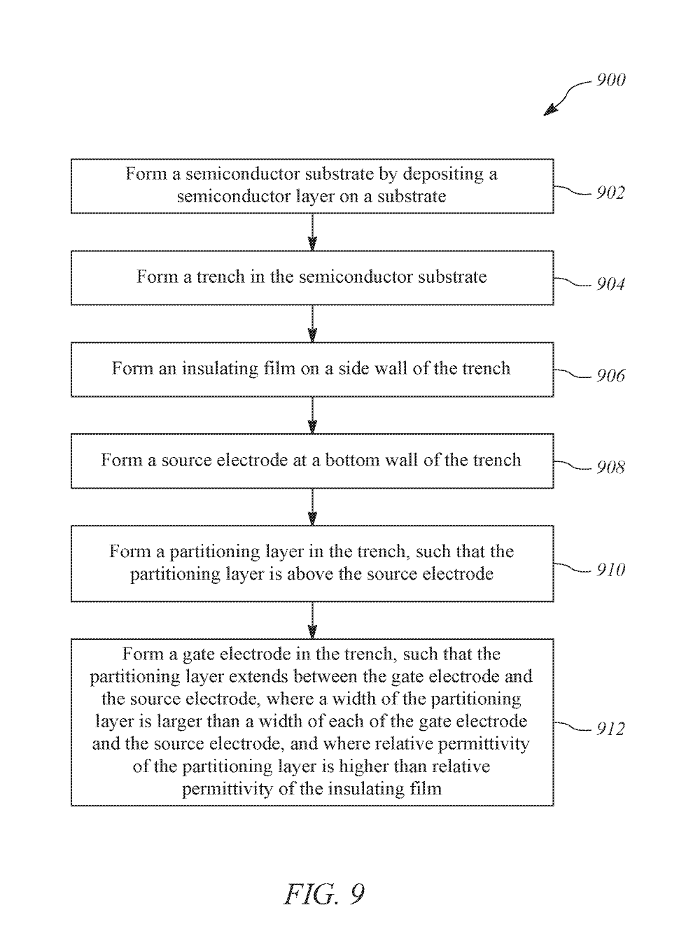

FIG. 9 illustrates a flowchart of a method 900 of fabricating the semiconductor device 100, according to one embodiment of the present disclosure. For the sake of brevity, the aspects of the present disclosure which are already explained in detail in relation to the description associated with FIG. 1(A), FIG. 1(B), FIG. 2, FIG. 4, FIG. 4, FIG. 5, FIG. 6, FIGS. 7(A) to 7(K), and FIG. 8, are not explained in detail with regard to the description of the method 900.

At step 902, the process 900 includes forming the semiconductor substrate 102 by depositing a semiconductor layer on substrate. In an example, the semiconductor substrate 102 is formed by epitaxially growing a drift region of a first conductivity type, for example, “N” conductivity type on a highly doped drain region of the first conductivity type, for example, “N+ conductivity type.

At step 904, the process 900 includes forming a trench 112 in the semiconductor substrate 102. The trench 112 includes a pair of opposing sidewalk, such as a first sidewall 114a and a second side-wall 114b. The trench 112 also includes a bottom wall 116.

At step 906, the process 900 includes forming an insulating film 122 on a sidewall of the trench 112. In an example, the insulating film 122 extends along the first sidewall 114a and the second sidewall 114b of the trench 112. In an example, the insulating film 122 comprises Silicon Dioxide (SiO₂). The relative permittivity of SiO₂ is 3.9.

At step 908, the process 900 includes forming a source electrode 120 at the bottom wall 116 of the trench 112. In an example, the source electrode 120 is formed by depositing polysilicon on a surface of the semiconductor substrate 102, such that the trench 112 is filled with the polysilicon.

At step 910, the process 900 includes forming a partitioning layer 124 in the trench 112, such that the partitioning layer 124 is above the source electrode 120. Relative permittivity of the partitioning layer 124 is higher than the relative permittivity of the insulating film 122. The partitioning layer 124 comprises at least one material from amongst Silicon nitride (Si₃N₄), Aluminium Oxide (Al₂O₃), Silicon (Si), Silicon carbide (SiC), and Gallium nitride (GaN). According to an example, the partitioning layer 124 is formed by using at least one of a sputtering technique, a Chemical Vapor Deposition (CVD) technique, and an epitaxial growth technique. Further, thickness of the partitioning layer 124 in the depth direction is in a range of about 50 Å to about 1000 Å. In an example, the thickness of the partitioning layer 124 in a central area of the partitioning layer in a width direction is more than the thickness of the partitioning layer 124 in a peripheral area of the partitioning layer in the width direction. The width direction being perpendicular to a depth direction of the trench. In an example, the partitioning layer 124 further comprises a plurality of layers, such that relative permittivity of layers disposed near the source electrode 120 is higher than relative permittivity of layers disposed near the gate electrode 118.

At step 912, the process 900 includes forming a gate electrode 118 in the trench 112, such that the partitioning layer 124 extends between the gate electrode 118 and the source electrode 120. In an example, the gate electrode 118 is formed by depositing a polysilicon on a surface of the semiconductor substrate 102, such that the trench 112 is filled with the polysilicon. A width of the partitioning layer 124 in a width direction is larger than a width of each of the gate electrode 120 and the source electrode 118 in the width direction. The width direction is perpendicular to a depth direction of the trench 112. For example, the width of the partitioning layer 124 is 1.2 to 2.5 times larger than the width of each of the gate electrode 118 and the source electrode 120.

While aspects of the present disclosure have been particularly shown and described with reference to the embodiments above, it will be understood by those skilled in the art that various additional embodiments may be contemplated by the modification of the disclosed devices and methods without departing from the spirit and scope of what is disclosed. Such embodiments should be understood o fall within the scope of the present disclosure as determined based upon the claims and any equivalents thereof.

1. A semiconductor device, comprising:
a semiconductor substrate;
a trench in the semiconductor substrate;
a gate electrode in the trench;
a source electrode in the trench, the source electrode being disposed between the gate electrode and a bottom wall of the trench;
a partitioning layer in the trench, the partitioning layer extending between the gate electrode and the source electrode; and
an insulating film in the trench.

2. The semiconductor device of claim 1, wherein a width of the partitioning layer in a width direction is larger than a width of each of the gate electrode and the source electrode in the width direction, the width direction being perpendicular to a depth direction of the trench.

3. The semiconductor device of claim 1, wherein relative permittivity of the partitioning layer is higher than relative permittivity of the insulating film.

4. The semiconductor device of claim 2, wherein the width of the partitioning layer is 1.2 times to 2.5 times larger than the width of each of the gate electrode and the source electrode.

5. The semiconductor device of claim 1, wherein thickness of the partitioning layer in a central area of the partitioning layer in a width direction is more than the thickness of the partitioning layer in a peripheral area of the partitioning layer in the width direction, the width direction being perpendicular to a depth direction of the trench.

6. The semiconductor device of claim 5, wherein a bottom surface of the partitioning layer closer to the source electrode than the gate electrode in the depth direction is flat, and upper surface of the partitioning layer closer to the gate electrode than the source electrode in the depth direction is convex.

7. The semiconductor device of claim 5, wherein a ratio of the thickness of the partitioning layer in the central area and the thickness of the partitioning layer in the peripheral area is greater than 1.2.

8. The semiconductor device of claim 1, wherein the partitioning layer comprises a plurality of layers, such that relative permittivity of a first layer of the plurality of layers is higher than relative permittivity of a second layer of the plurality of layers, the first layer being disposed closer to the source electrode than the second layer, and the second layer being disposed closer to the gate electrode than the first layer.

9. The semiconductor device of claim 8, wherein an edge of each of the plurality of layers of the partitioning layer is on a same plane.

10. The semiconductor device of claim 1, wherein the partitioning layer comprises at least one of Silicon nitride (Si₃N₄), Aluminum Oxide (Al₂O₃), Silicon (Si), Silicon carbide (SiC), and Gallium nitride (GaN).

11. The semiconductor device of claim 1, wherein the insulating film comprises Silicon Dioxide (SiO₂).

12. The semiconductor device of claim 1, wherein the insulating film further extends between the partitioning layer and a sidewall of the trench.

13. The semiconductor device of claim 1, wherein thickness of the partitioning layer in the depth direction is in a range of 50 Å to 1000 Å.

14. A semiconductor device, comprising:
a semiconductor substrate, the semiconductor substrate including a drain layer of first conductivity type, a drift layer of the first conductivity type, a base layer of a second conductivity type different from the first conductivity type, and a source layer of the first conductivity type layered in this order from a bottom of the semiconductor substrate;
a trench ire the semiconductor substrate;
a gate electrode in the trench;
a source electrode in the trench, the source electrode being disposed between the gate electrode and a bottom wall of the trench;
a partitioning layer in the trench, the partitioning layer extending between the gate electrode and the source electrode; and
an insulating film in the trench, wherein
a width of the partitioning layer in a width direction is larger than a width of each of the gate electrode and the source electrode in the width direction, the width direction being perpendicular to a depth direction of the trench, and
relative permittivity of the partitioning layer is higher than relative permittivity of the insulating film.

15. The semiconductor device of claim 14, wherein the width of the partitioning layer is 1.2 times to 2.5 times larger than the width of each of the gate electrode and the source electrode.

16. The semiconductor device of claim 14, wherein thickness of the partitioning layer in a central area of the partitioning layer in the width direction is more than the thickness of the partitioning layer in a peripheral area of the partitioning layer in the width direction.

17. The semiconductor device of claim 16, wherein a bottom surface of the partitioning layer closer to the source electrode than the gate electrode in the depth direction is flat, and upper surface of the partitioning layer closer to the gate electrode than the source electrode in the depth direction is convex.

18. The semiconductor device of claim 16, wherein a ratio of the thickness of the partitioning layer in the central area and the thickness of the partitioning layer in the peripheral area is greater than 1.2.

19. The semiconductor device of claim 14, wherein the partitioning layer comprises a plurality of layers, such that relative permittivity of a first layer of the plurality of layers is higher than relative permittivity of a second layer of the plurality of layers, the first layer being disposed closer to the source electrode than the second layer, and the second layer being disposed closer to the gate electrode than the first layer.

20. The semiconductor device of claim 19, wherein an edge of each of the plurality of layers of the partitioning layer is on a same plane.
